(19) United States
(12) Patent Application Publication
(10) Pub. No.: US 2008/0117600 A1
(43) Pub. Date: May 22, 2008

(54) CLAMPING SYSTEM FOR AREAS WITH LIMITED ACCESSIBILITY

(75) Inventors: Michael J. Wayman, Waconia, MN (US); Eric s. Moreau, St. Peter, MN (US); Jennifer L. Casey, Eagan, MN (US)

Correspondence Address: FOGG & POWERS LLC, 10 SOUTH FIFTH STREET, SUITE 1000, MINNEAPOLIS, MN, 55402, US

(73) Assignee: ADC TELECOMMUNICATIONS, INC., Eden Prairie, MN (US)

(21) Appl. No.: 11/561,516

(22) Filed: Nov. 20, 2006

(51) Int. Cl. H05K 7/20; B23P 17/00; F16B 2/02

(52) U.S. Cl. 361/709; 29/592; 24/455

(57) ABSTRACT

A clamping system is disclosed that includes at least one rigid clamp member. The rigid clamp member has an angled surface operable to hold a structure against a mounting surface, and the rigid clamp member is configured to be attached to the mounting surface. The clamping system also includes at least one adjustable clamp member. The adjustable clamp member has an angled adjustable surface operable to hold the structure against the mounting surface. Additionally, the adjustable clamp member is configured to be attached to the mounting surface.

### BACKGROUND

The task of clamping one structure to another can be complicated by many factors. One such complication occurs when the structures must be clamped in an area that is difficult to access. Although the clamping of structures occurs in almost all industries, limited accessibility clamping is a large problem when dealing with the ever shrinking components in the electronics industry.

One structure in the electronics industry that commonly requires clamping is the heat sink of a circuit board. The heat sink facilitates conduction between the circuit board and a larger enclosure or chassis that contains the circuit board. To be effective, conduction requires a strong, solid contact between the two conducting surfaces. Thus, strong contact must be made between the heat sink and both the circuit board and the enclosure respectively. Contact between the heat sink and circuit board is often taken care of right during production as the heat sink is factory assembled to the circuit board. Once the circuit board arrives at its final destination, however, the entire circuit board assembly must then be mounted onto the enclosure in such a way that the heat sink makes strong contact with the enclosure. Ensuring strong contact between the heat sink and the enclosure can be difficult, however, because the circuit board is often much larger than the heat sink and there is often limited space around the circuit board in the enclosure.

Often, the only reasonable way to ensure strong contact with the enclosure is to clamp the heat sink. Screw attachment of the heat sink may be difficult, because heat sinks are often generically designed and may not have screw holes or tabs to match the enclosure. Additionally, once the heat sink has been assembled, modification of the heat sink is not a cost effective option. Since the heat sink and circuit board are typically factory assembled, the possibility of first mounting the heat sink to the enclosure and later mounting the circuit board on top is eliminated.

For the reasons stated above, and for other reasons stated below which will become apparent to those skilled in the art upon reading and understanding the present specification, there is a need in the art for an apparatus that allows for clamping a structure down in an area with limited accessibility.

### SUMMARY

The present invention relates to a clamping system that includes at least one rigid clamp member. The rigid clamp member has an angled surface operable to hold a structure against a mounting surface, and the rigid clamp member is configured to be attached to the mounting surface. The clamping system also includes at least one adjustable clamp member. The adjustable clamp member has an angled adjustable surface operable to hold the structure against the mounting surface. Additionally, the adjustable clamp member is configured to be attached to the mounting surface.

### BRIEF DESCRIPTION OF THE DRAWINGS

The present invention can be more easily understood and further advantages and uses thereof are more readily apparent, when considered in view of the detailed description and the following figures in which:

FIG. 1 is a cross-sectional view of one embodiment of a system for clamping a structure in an area with limited accessibility;

FIG. 2 is a cross-sectional view of one embodiment of a first clamp member shown in FIG. 1;

FIG. 3 is a cross-sectional view of one embodiment of a second clamp member shown in FIG. 1;

FIG. 4A is a front perspective view of the second clamp member of FIG. 3;

FIG. 4B is a back perspective view of the second clamp member of FIG. 3;

FIG. 5 is a flow diagram of one embodiment of a method of clamping a structure to a mounting surface;

FIG. 6 is a perspective view of one embodiment of a body that can be formed into a clamp member; and

FIG. 7 is a flow diagram of one embodiment of a method of forming a clamp member.

In accordance with common practice, the various described features are not drawn to scale but are drawn to emphasize specific features relevant to the present invention. Like reference characters denote like elements throughout the Figures and text of the detailed description.

### DETAILED DESCRIPTION

In the following detailed description, reference is made to the accompanying drawings that form a part hereof, and in which is shown by way of illustration, specific illustrative embodiments in which the invention may be practiced. These embodiments are described in sufficient detail to enable those skilled in the art to practice the invention, and it is to be understood that other embodiments may be utilized and that mechanical and structural changes may be made without departing from the spirit and scope of the present invention. The following detailed description is, therefore, not to be taken in a limiting sense.

The present clamping system provides an easy way to clamp a structure to a surface when the structure must be clamped in an area with limited accessibility. For example, such a structure can be a small heat sink located under a large circuit board and the heat sink must be clamped to an enclosure. The accessibility of a heat sink under a circuit board can be improved by placing the heat sink near the edge of the circuit board. Even this, however, usually allows access to only one side of the circuit board. The present system is designed, therefore, to securely clamp a structure, such as a heat sink, while requiring access to only one side of the structure.

The present clamping system comprises two or more clamp members. At least one clamp member is a rigid clamp member that is placed on the inaccessible side of the structure to be clamped. Also, at least one clamp member is an adjustable clamp member that is placed adjacent the structure and opposite of the rigid clamp member. The adjustable clamp member forces the structure downward and against the rigid clamp member. When pushed against the rigid clamp member, the structure receives a reactive force both lateral and downward to hold the structure in place. One use of the clamping system is to provide a downward clamp load sufficient to allow proper heat transfer from a heat sink to an enclosure surface.

The present system has many operational advantages. It can clamp many structures of varying shapes and sizes with no modification to the clamped structure. This is very beneficial for use with off the shelf heat sinks that lack custom mounting holes or small factor heat sinks with no space for such holes. The clamping system is also easy to use, as a single screw is sufficient to mount, support and adjust the adjustable clamp. In addition to its operational advantages, the present system has a cost-effective design that requires only two clamp members. Each clamp member uses only a single piece of sheet metal and requires no additional value added steps, e.g. welding, to maintain the structure. Finally, the clamp members are easily scalable to different sized structures and different clamping force needs. A simple change in the material of construction, or the size or thickness of the sheet metal changes the effective spring constant and accommodates different clamping requirements.

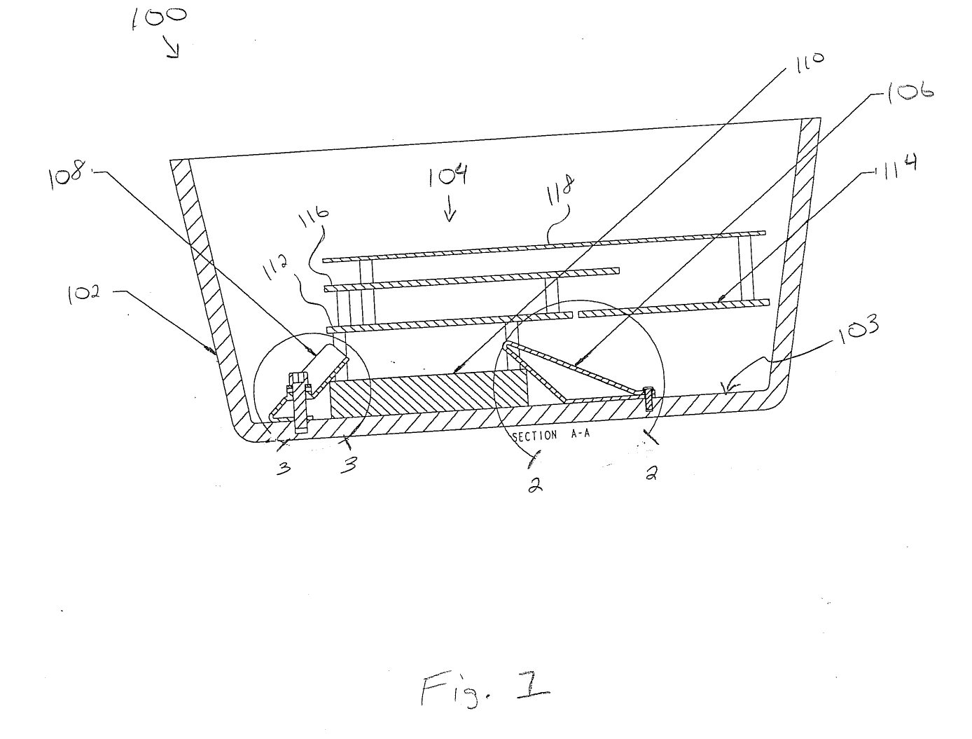

FIG. 1 illustrates one example of a device 100 that can employ the present system and method for clamping a structure in an area with limited accessibility. In one embodiment, device 100 comprises an enclosure 102 which can be composed of metal and cast into the desired shape. Enclosure 102 has a mounting surface 103 with a mountable structure such as a circuit board assembly 104 attached thereto by the present clamping system, including a rigid first clamp member 106 and an adjustable second clamp member 108.

In one embodiment, circuit board assembly 104 comprises a heat sink 110, a first circuit board 112, a second circuit board 114, a third circuit board 116, and a carrier chassis 118. The circuit board assembly 104 can be fully assembled at a factory, with assembly 104 being sent to another location before mounting to enclosure 102. At the factory, assembly of circuit board assembly 104 begins by mounting heat sink 110 to first circuit board 112. The first circuit board 112 and heat sink 110 are then connected to second circuit board 114 and third circuit board 116. The resulting assembly of heat sink 110, first circuit board 112, second circuit board 114, and third circuit board 116 is mounted on carrier chassis 118. In one embodiment, carrier chassis 118 is composed of sheet metal and provides support to the circuit boards. The support of carrier chassis 118 is necessary to withstand the shock that occurs during transportation of circuit board assembly 104.

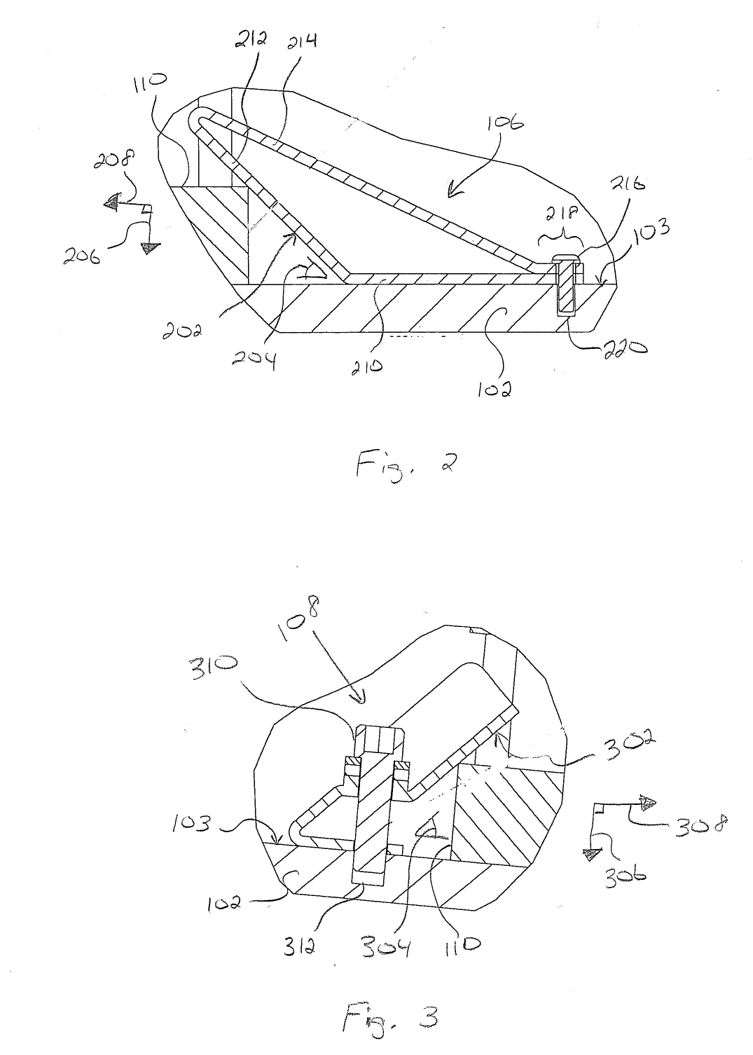

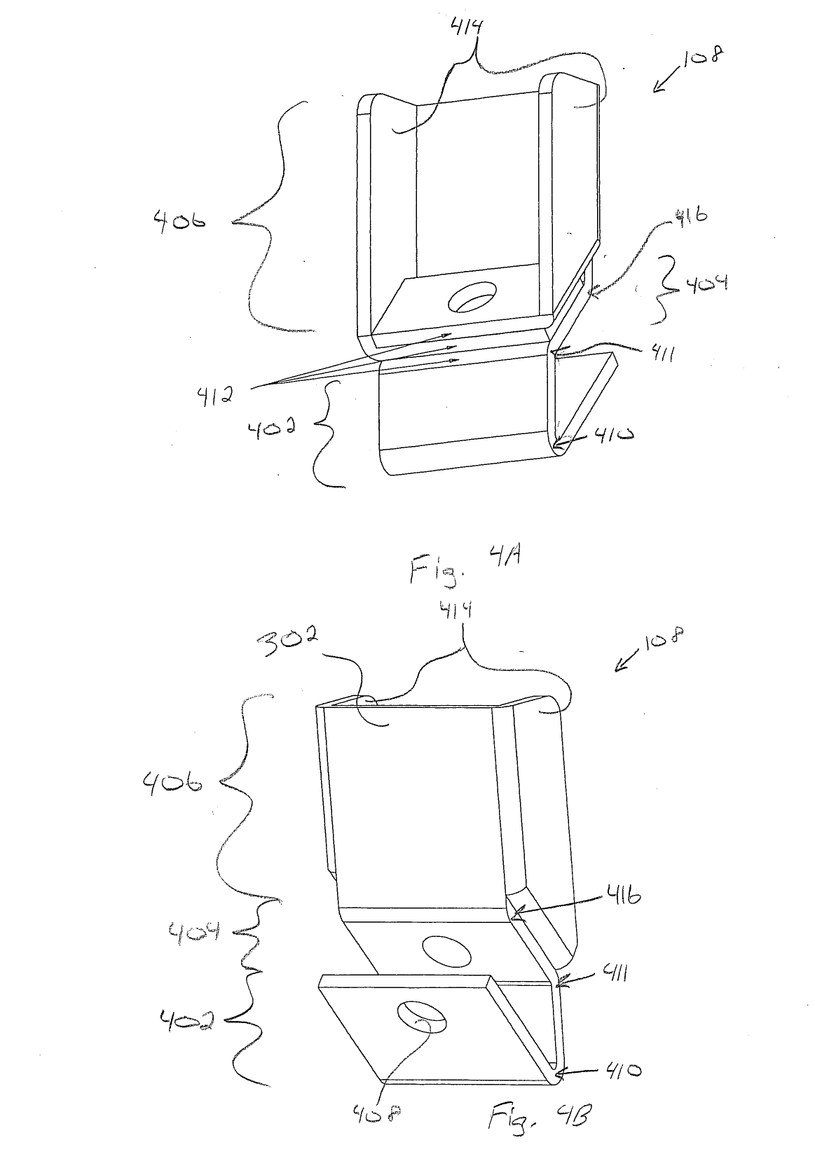

In another embodiment, heat sink 110 is mounted directly to a processor and the processor is on a single large circuit board. Alternatively, heat sink 110 could be mounted on a circuit board assembly of any size or containing any number of circuit boards as long as there is access to at least one side of heat sink 110. More detail regarding first clamp member 106 and second clamp member 108 is provided as follows by referring to FIGS. 2 and 3 respectively.

FIG. 2 illustrates a cross-sectional view of one embodiment of first clamp member 106. First clamp member 106 has a contact surface 202 oriented at a downward angle 204 relative to mounting surface 103 of enclosure 102. Contact surface 202 is oriented downward to provide both a downward force 206 and an inward force 208 against heat sink 110. Thus, a lateral force from heat sink 110 against contact surface 202 results in heat sink 110 being pressed against mounting surface 103 by downward force 206. Angle 204 of contact surface 202 can be from about 0°-90° as long as contact surface 202 can produce a downward force 206 and an inward force 208 on heat sink 110. In one embodiment, contact surface 202 has a downward angle 204 in the range of about 35° to about 55° with respect to mounting surface 103.

In one embodiment, first clamp member 106 has a generally triangular shaped cross-section such as an obtuse triangular shape. In this embodiment, first clamp member 106 has a bottom side 210, a contact side 212 and a support side 214. Bottom side 210 allows first clamp member to be easily mounted to enclosure 102. Contact side 212 extends from bottom side 210 and is angled generally downward to provide contact surface 202 with the proper angle 204. Support side 214 connects the far end of bottom side 210 with the far end of contact side 212. Support side 214 supports the contact side 212 and improves the ability of contact surface 202 to provide reactive force upon heat sink 110 as heat sink 110 is pushed against contact surface 202.

In one embodiment, first clamp member 106 can be attached to enclosure 102 by placing a pan head screw 216 through securing point 218. Securing point 218 extends outside the triangle of first clamp member 106 from the corner between support side 214 and bottom side 210. Pan head screw 216 is inserted through first clamp member 106 at securing point 218 and screwed into enclosure 102 at an aperture 220 to attach first clamp member 106 to mounting surface 103 of enclosure 102.

In one embodiment, first clamp member 106 is composed of a unitary piece of sheet metal. Constructing first clamp member 106 out of a single piece of sheet metal is cost effective, because clamp member 106 does not require many manufacturing steps. First clamp member 106 can be constructed by cutting a piece of sheet metal into a strip. The strip of sheet metal is then bent in three places to form the bottom side 210, contact side 212, support side 214, and securing point 218 of first clamp member 106. In one embodiment, before the strip of sheet metal is bent, one aperture is drilled at each end of the strip. When first clamp member 106 is bent to form its generally triangular cross-section each aperture is aligned to allow pan head screw 216 to be placed through the apertures and screwed into enclosure 102. In another embodiment, both apertures are drilled after bending first clamp member 106 into its triangular cross-section.

In another embodiment, first clamp member 106 is a solid structure, i.e. first clamp member 106 does not have a hollow cross-section as shown in FIG. 2. In this embodiment, first clamp member is composed of plastic. Alternatively, first clamp member 106 could be made of any material with sufficient stiffness and strength that contact surface 202 can provide sufficient force on heat sink 110. Additionally, first clamp member 106 could be shapes other than triangular as long as contact surface 202 is angled to apply downward force 206 on heat sink 110. Finally, securing point 218 could be moved to another location on first clamp member 106 as long as first clamp member 106 can still be secured to enclosure 102.

Referring now to FIG. 3, a cross-sectional view of one embodiment of second clamp member 108 is shown. Second clamp member 108 has a contact surface 302 oriented at a downward angle 304 relative to mounting surface 103 of enclosure 102. Similar to contact surface 202 of first clamp member 106, contact surface 302 is oriented downward to provide both a downward force 306 and an inward force 308 against heat sink 110. In one embodiment, contact surface 302 has a downward angle 304 in the range of about 35° to about 55° with respect to mounting surface 103. A load screw 310 secures second clamp member 108 to enclosure 102 at an aperture 312 and can be tightened to apply force to heat sink 110.

FIGS. 4A and 4B are front and rear perspective views of one embodiment of a second clamp member 108. Second clamp member 108 comprises a spring portion 402, a seat portion 404, and a contact portion 406. Spring portion 402 defines an aperture 408 for load screw 310 (shown in FIG. 3). Aperture 408 is placed on mounting surface 103 of enclosure 102 and load screw 310 is inserted through aperture 408 and into enclosure 102. Thus, one function of load screw 310 is to secure second clamp member 108 to enclosure 102. From aperture 408, spring portion 402 is bent in two places to form corners 410, 411 before connecting with seat portion 404. In one embodiment, corners 410, 411 formed in the spring portion 402 act as pivot points that allow seat portion 404 and contact portion 406 to move relative to aperture 408. In another embodiment, spring portion 402 has a constant gentle curve from aperture 408 to seat portion 404. Alternatively, spring portion 402 could be of any design sufficient to allow contact portion 406 to move.

In one embodiment, seat portion 406 has three layers 412, each layer defining an aperture for load screw 310. Here, load screw 310 functions as a support mechanism by holding second clamp member 108 together as load screw 310 is placed through the three apertures in seat portion 404. Additionally, seat portion 404 supports the head of load screw 310 such that load screw 310 when inserted into aperture 312 will pull seat portion 404 towards mounting surface 103 of enclosure 102. Contact portion 406 has three sides, including one side having a contact surface 302 and two support sides 414. The contact surface 302 applies force to heat sink 110. Each support side 414, in one embodiment, is connected to contact surface 302 and also connected to one layer 412 of seat portion 404. Each support side 414 can also be positioned substantially normal to contact surface 302, such that support sides 414 in combination with the attached layers 412 of seat portion 404 can support contact surface 302 during application of force by contact surface 302.

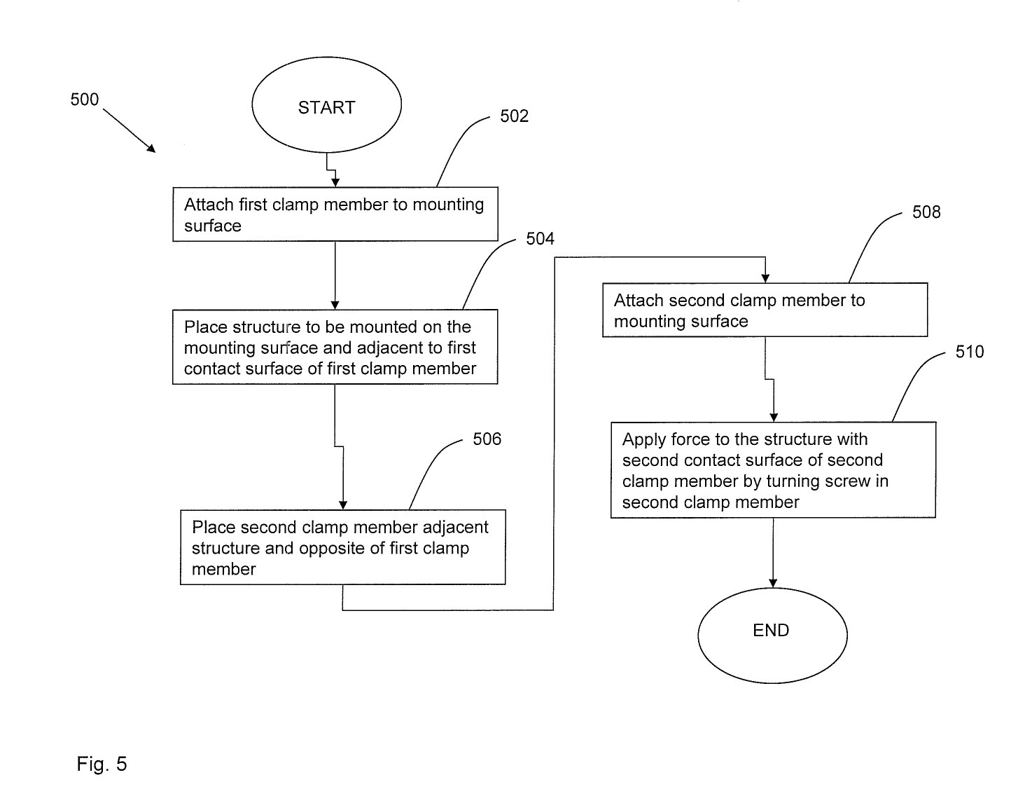

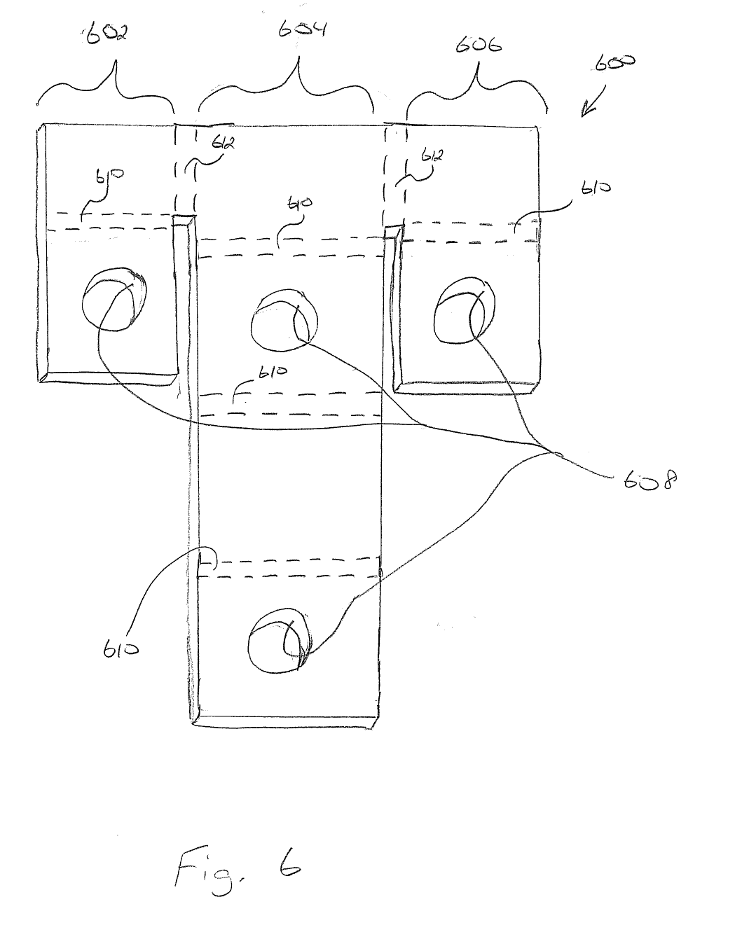

Referring now to FIG. 5, one embodiment of a method 500 to clamp heat sink 110 down in a limited access area is shown. To begin, first clamp member 106 is attached to mounting surface 103 (502). Fist clamp member 106 should be placed where the inaccessible side of heat sink 110 will be after installation. Here, first clamp member 106 is stationary, and clamps heat sink 110 down via a reactive force when heat sink 110 is pushed against first clamp member 106. Once first clamp member 106 is installed, heat sink 110 is placed on mounting surface 103 and adjacent contact surface 202 of first clamp member 106 (504). Next, heat sink 110 is slid firmly against first clamp member 106 so that contact surface 202 is abutted against an edge of heat sink 110 (shown in FIG. 2).

Once heat sink 110 is in place, second clamp member 108 is placed adjacent heat sink 110 on the opposite side from first clamp member 106 (506). Second clamp member 108 is then attached to mounting surface 103 (508). For example, load screw 310 can be inserted through apertures in second clamp member 108 and into aperture 312 (shown in FIG. 3). Load screw 310 is then tightened, thereby deflecting second clamp member 108 and applying force against heat sink 110 in a downward and lateral angle (510). Second clamp member 108 is adjustable and can move contact surface 302 against heat sink 110 to apply force to heat sink 110. The lateral force on heat sink 110 will, in turn, be exerted against first clamp member 106 and will cause a lateral and downward reactive force by first clamp member 106. Thus, tightening load screw 310 causes heat sink 110 to be clamped downward from both sides. Load screw 310 can be tightened to provide the desired clamping force.

Referring back to FIG. 3, more detail regarding the operation of second clamp member 108 will now be provided. As stated above, second clamp member 108 is placed on mounting surface 103 of enclosure 102 adjacent to heat sink 110. Then, load screw 310 is placed through the apertures in the seat portion 404 and the spring portion 402 and into aperture 312 of enclosure 102. Load screw 310 is then tightened downward which deflects spring portion 402 at corners 410, 411. The deflection of spring portion 402 causes contact surface 302 to be lowered against heat sink 110. The force placed upon heat sink 110 can be increased by tightening load screw 310 and decreased by loosening load screw 310.

As the force applied by second clamp member 108 increases, deflection may also occur at corner 416. Deflection at corner 416 will effectively reduce the force actually applied to heat sink 110. The force applied by second clamp member 108 can be increased by reducing the deflection at corner 416. In one embodiment, this defection can be reduced by increasing the thickness of the sheet metal used to construct second clamp member 106. Increasing the thickness of the sheet metal increases the effective spring constant of the second clamp member 108 and increases the amount of force transferred from the tightening of load screw 310. In another embodiment, the spring constant of second clamp member 108 is adjusted by using a different material, e.g. plastic. Alternatively, any material that is stiffer or more pliable can be used to change the spring constant accordingly.

In other embodiments, multiple clamp members can be used on each side of the clamped structure. For example, two or more first clamp members 106 can be located adjacent to one another on one side of heat sink 110. Two or more second clamp members 108 can also be located adjacent each other on the opposite side of heat sink 110 from first clamp members 106. Alternatively, clamp members could be placed on all sides of a structure as long as the positioning of the clamp members allows the structure to be slid up against the first clamp members 106 and clamped on the opposite side by at least one second clamp member 108. Each first clamp member 106 need not have an exactly matching second clamp member 108. For example, one second clamp member 108 could be used to clamp a circular structure with two first clamp members 106 located 120° away in each direction around the circular structure from the second clamp member 108. In another embodiment, the width of each of the clamp members is varied to, e.g., provide additional force, spread the force more evenly across the clamped structure, or avoid abnormalities of the structure.

FIG. 6 illustrates one embodiment of a body 600 that can be formed into an adjustable clamp member such as second clamp member 108. Body 600 has first elongated member 602, second elongated member 604, and third elongated member 606. Elongated members 602, 604, 606 have apertures 608. Additionally, elongated members 602, 604, 606 are bent in areas 610, as well as at intersections 612.

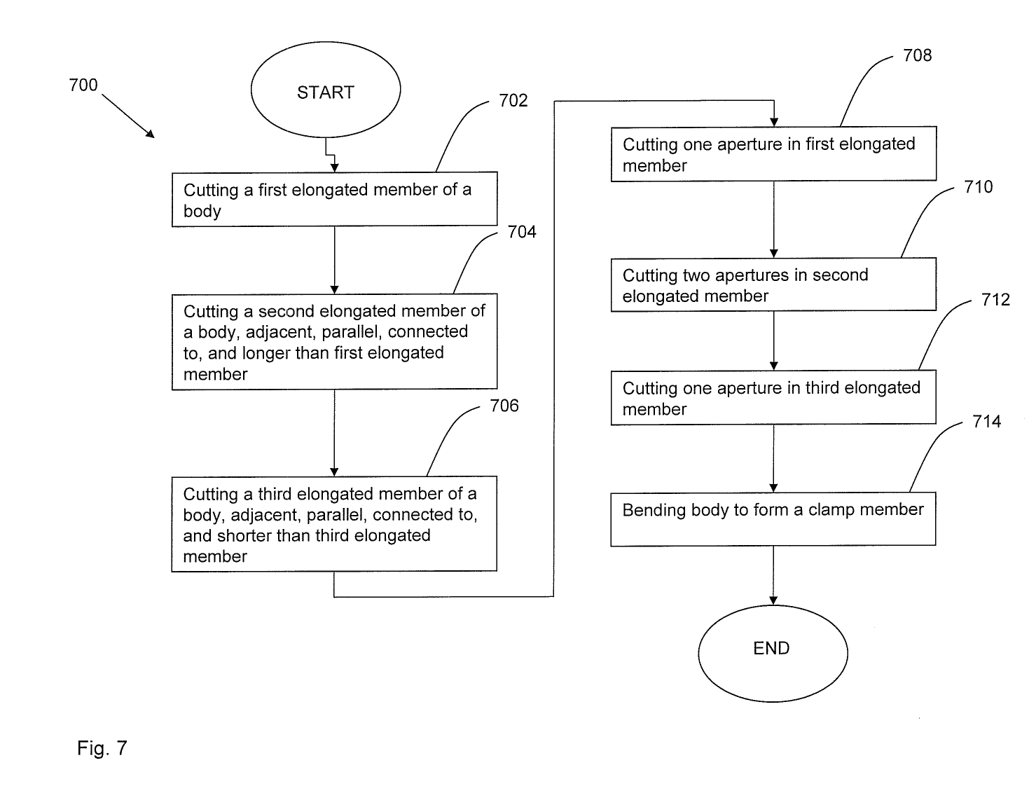

One method of manufacturing an adjustable clamp member such as second clamp member 108 is shown in FIG. 7. Body 600 is first formed from one piece of sheet metal and is a unitary piece of metal. In one embodiment, the outline of body 600 is cut from the sheet metal by, e.g., a laser. Alternatively, body 600 could be cut with a saw, knife, or any other method as is known to those skilled in the art. In one embodiment, body 600 is composed primarily of three substantially elongated members. To form body 600 a single piece of sheet metal is cut to form first elongated member 602, second elongated member 604, and third elongated member 606. First elongated member 602 is cut as the shortest of the three elongated members (702). Next, second elongated member 604 is cut so that it is parallel, adjacent, and connected to first elongated member 602 (704). Second elongated member is the longest of the three elongated members. Third elongated member 606 is cut so that it is parallel, adjacent and connected to second elongated member 604 (706). Third elongated member 606 has a length that is slightly longer than the first elongated member 602, but substantially shorter than the second elongated member 604. All three elongated members 602, 604, 606 are cut connected to each other so that they only require the additional steps of forming apertures 608 to form body 600. The three elongated members are formed parallel to each other and remain connected at one end such that all of the elongations point in the same direction. In one embodiment, apertures 608 are cut with a laser or drilled out with a drill.

Apertures 608 can be formed prior or after cutting elongated members 602, 604, 606. One aperture 608 is cut in the first elongated member 602 (708). Two apertures 608 are cut in the second elongated member 604 (710). Finally, one aperture 608 is cut in the third elongated member 606 (712).

In one embodiment, once body 600 has been formed, body 600 can be bent into second clamp member 108 (714). Body 600 is bent in areas 610 and intersections 612 between the dotted lines shown in FIG. 6. Second elongated member 604 is bent in three areas 610 to form spring portion 402, the bottom layer of seat portion 404, and contact surface 302 on contact portion 406. Next, third elongated member 606 is bent in one area 610 and body 600 is bent at intersection 612 of second elongated member 604 and third elongated member 606 to form the middle layer of seat portion 404 as well as one of support sides 414. Finally, first elongated member 602 is bent in one area 610 and body 600 is bent at intersection 612 of first elongated member 602 and second elongated member 604 to form the other support side 414 of the contact portion 406, and the top layer of seat portion 404. Each elongated member is bent so that the apertures of each member align with one another and allow a screw to be inserted through the apertures.

In another embodiment, first elongated member 602 is slightly longer than third elongated member 606 and accounts for the bottom layer of seat portion 404. In this embodiment, second elongated member 604 and third elongated member 606 account for the middle and top layers of seat portion 404 respectively. Alternatively, the lengths of elongated members 602, 604, 606 could be modified in any way to change the layers in seat portion 404. In yet another embodiment, elongated members 602, 604, 606 are rounded to provide a smoother contour for second clamp member 108 while the general shape of body 600 is retained.

Manufacturing the clamp members from a single piece of sheet metal is cost effective, simple, and adjustable. When constructing clamp members 106, 108, the width of the sheet metal can be selected based on the desired force to be applied to the clamped structure. Thicker sheet metal does not flex as easily, thus, thicker sheet metal can place a higher clamping load on the clamped structure. Likewise, thinner sheet metal gives more freely and could be used to place a lower clamping force on the clamped structure. Alternatively, the clamping force can be adjusted by changing the size of the clamp members 106, 108 or the material with which the clamp members 106, 108 are made. This effectively changes the spring constant of the clamp members 106, 108.

Although specific embodiments have been illustrated and described herein, it will be appreciated by those of ordinary skill in the art that any arrangement, which is calculated to achieve the same purpose, may be substituted for the specific embodiments shown. This application is intended to cover any adaptations or variations of the present invention. Therefore, it is manifestly intended that this invention be limited only by the claims and the equivalents thereof.

What is claimed is:

1. A clamping system, comprising:
at least one rigid clamp member comprising:
an angled surface operable to hold a structure against a mounting surface; and
wherein the rigid clamp member is configured to be attached to the mounting surface; and
at least one adjustable clamp member comprising:
an angled adjustable surface operable to hold the structure against the mounting surface; and
wherein the adjustable clamp member is configured to be attached to the mounting surface.

2. The system of claim 1, wherein the rigid clamp member comprises a single piece of sheet metal.

3. The system of claim 1, wherein the adjustable clamp member comprises a single piece of sheet metal.

4. The system of claim 1, wherein the at least one rigid clamp member has a generally triangular cross-section.

5. The system of claim 1, wherein the at least one rigid clamp member is hollow.

6. The system of claim 1, wherein the at least one rigid clamp member is solid.

7. The system of claim 1, wherein the at least one rigid clamp member has an obtuse triangular cross-section.

8. The system of claim 1, further comprising:
a screw operable to move the angled adjustable surface of the at least one adjustable clamp member.

9. The system of claim 1, wherein the adjustable clamp member further comprises:
a spring portion that allows the adjustable surface to move.

10. The system of claim 1, wherein the angled surface of the rigid clamp member has a range of about 35 to about 55 degrees relative to the mounting surface.

11. The system of claim 1, wherein the angled adjustable surface of the adjustable clamp member has a range of about 35 to about 55 degrees relative to the mounting surface.

12. An apparatus for use in a clamping system, the apparatus comprising:
a spring portion defining an aperture;
a seat portion connected to the spring portion and defining at least one aperture, the at least one aperture of the seat portion being substantially aligned with the aperture of the spring portion; and
a contact portion connected to the seat portion, the contact portion having an angled contact surface, wherein the spring portion allows the contact portion to move.

13. The apparatus of claim 12, wherein the spring portion, seat portion, and contact portion comprise a single piece of sheet metal.

14. The apparatus of claim 12, further comprising a screw placed through the aperture in the seat portion and the aperture in the spring portion.

15. The apparatus of claim 14, wherein the screw is operable to flex the spring portion thereby moving the contact portion towards a mounting surface.

16. The apparatus of claim 12 wherein the aperture of the spring portion is configured to be placed over a mounting surface.

17. The apparatus of claim 12, wherein the seat portion is operable to support a head of a screw.

18. The apparatus of claim 12, wherein the contact portion further comprises:
a contact surface and two opposing support sides, each of the support sides positioned substantially normal to the contact surface.

19. The apparatus of claim 12, wherein the contact portion is configured to apply force to a structure at an angle relative to a mounting surface.

20. An apparatus for use in a clamping system, the apparatus comprising:
a base side configured to be placed on a mounting surface;
a contact side extending at an angle from the base side and having a contact surface;
a support side extending from one end of the base side to one end of the contact side; and
a securing point extending from a corner where the base side and support side meet;
wherein the apparatus has a generally triangular cross-section.

21. The apparatus of claim 20, wherein the base side, contact side, and support side are a unitary strip of sheet metal.

22. The apparatus of claim 21, wherein the unitary strip of sheet metal comprises:
a first end defining an aperture; and
a second end defining an aperture, wherein the first end and the second end form the securing point.

23. The apparatus of claim 22, wherein the aperture in the first end of the strip and the aperture in the second end of the strip substantially align.

24. The apparatus of claim 22, further comprising a screw placed through the aperture in the first end of the strip and the aperture in the second end of the strip.

25. The apparatus of claim 20, wherein the generally triangular cross-section comprises an obtuse triangle.

26. A method of clamping a structure to a mounting surface, the method comprising:
attaching a first clamp member to the mounting surface, the first clamp member having a first contact surface angled relative to the mounting surface;
placing the structure on the mounting surface and adjacent to the first contact surface of the first clamp member;
attaching a second clamp member to the mounting surface, the second clamp member having a second contact surface angled relative to the mounting surface, the second clamp member having a screw; and
applying force to the structure with the second contact surface of the second clamp member by turning the screw of the second clamp member.

27. A method of manufacturing a clamp member, the method comprising:
forming a body out of metal comprising:
forming a first elongated member;
forming a second elongated member adjacent and parallel to the first elongated member, the second elongated member being longer than the first elongated member; and
forming a third elongated member adjacent and parallel to the second elongated member, the third elongated member shorter than the second elongated member;
forming at least one aperture in the body; and
bending the body to form a clamp member.

28. The method of claim 27, wherein forming the body comprises:
cutting a single piece of sheet metal.

29. An electronic device comprising:
an enclosure having a mounting surface;
a circuit board assembly within the enclosure and including a heat sink;
a clamping system for holding the heat sink against the mounting surface, the clamping system comprising:
at least one rigid clamp member attached to the mounting surface and comprising:
a base side on the mounting surface;
a contact side extending at an angle from the base side and having an angled contact surface; and
a support side extending from one end of the base side to one end of the contact side;
wherein the angled contact surface of the contact side abuts against the heat sink; and
at least one adjustable clamp member attached to the mounting surface and comprising:
a spring portion;
a seat portion connected to the spring portion; and
a contact portion connected to the seat portion, the contact portion having an angled contact surface;
wherein the spring portion allows the contact portion to be tightened against the heat sink.
